(19) United States
(12) Patent Application Publication
(10) Pub. No.: US 2011/0005574 A1
(43) Pub. Date: Jan. 13, 2011

(54) Sleeve for protecting a wire of a solar cell module

(75) Inventor: Hwa-Yuh Shin, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 12/010,307

(22) Filed: Jan. 23, 2008

(51) Int. Cl. H01L 31/05

(52) U.S. Cl. 136/246

(57) ABSTRACT

A solar cell module includes a plurality of solar cells, a plurality of wire units and a plurality a plurality of lenses over the solar cells for focusing light into light spots on the solar cells. Each of the wire units includes a wire for interconnecting two adjacent ones of the solar cells and a sleeve for receiving and protecting the wire from heat.

### FIELD OF THE INVENTION

The present invention relates to sleeve for protecting a wire of a solar cell module and, more particularly, to a sleeve for protecting a wire of a solar cell module from heat, acid, alkali and erosion.

### DESCRIPTION OF THE RELATED ARTS

To reduce the cost, not many special sleeves have devised to protect wires of solar cell modules. In a concentration solar cell module, sunlit is focused onto light spots of high energy densities. The temperature at the light spots reaches hundreds of degrees Celsius. The light spots are supposed to fall on solar cells of small areas and high photovoltaic efficiencies. But if the light spots fall on the wires, the wires would be burnt and damaged, thus rendering the concentration solar cell module out of order.

The present invention is therefore intended to obviate or at least alleviate the problems encountered in prior art.

### SUMMARY OF THE INVENTION

It is the primary objective of the present invention to provide a solar cell module that survives heat.

To achieve the foregoing objective, the solar cell module includes a plurality of solar cells, a plurality of wire units and a plurality of lenses over the solar cells for focusing light into light spots on the solar cells. Each of the wire units includes a wire for interconnecting two adjacent ones of the solar cells and a sleeve for receiving and protecting the wire from heat.

Other objectives, advantages and features of the present invention will become apparent from the following description referring to the attached drawings.

### BRIEF DESCRIPTION OF THE DRAWINGS

The present invention will be described via detailed illustration of the preferred embodiment referring to the drawings.

FIG. 1 is a perspective view of a sleeve for protecting a wire of a solar cell module according to the preferred embodiment of the present invention.

FIG. 2 is a perspective view of the wire inserted in the sleeve of FIG. 1.

FIG. 3 is a perspective view of a solar cell module including wires and sleeves as shown in FIG. 1.

### DETAILED DESCRIPTION OF EMBODIMENT

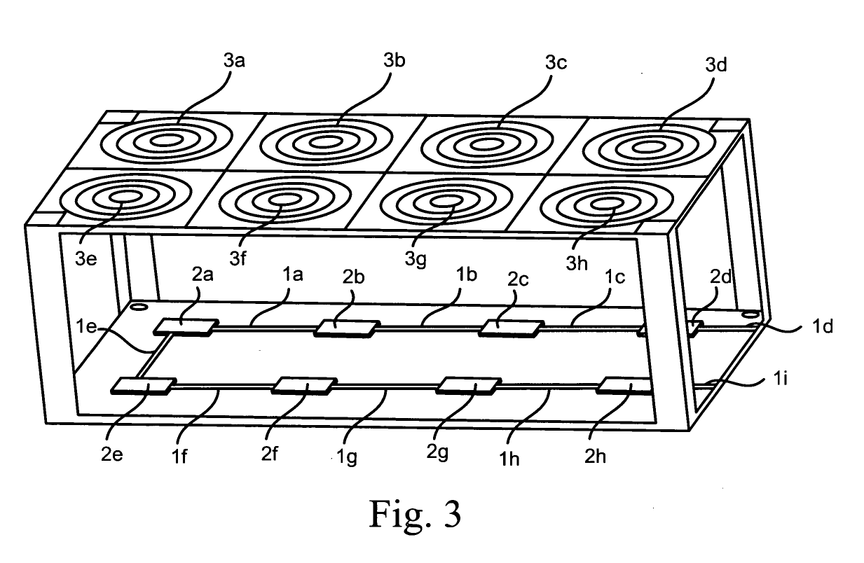

Referring to FIG. 3, there is shown a concentration solar cell module includes solar cells 2a, 2b, 2c, 2d, 2e, 2f, 2g and 2h, wire units 1a, 1b, 1c, 1d, 1e, 1f, 1g and 1h for connecting the solar cells 2a, 2b, 2c, 2d, 2e, 2f, 2g and 2h to one another and lenses 3a, 3b, 3c, 3d, 3e, 3f, 3g and 3h for focusing sunlit into light spots on the solar cells 2a, 2b, 2c, 2d, 2e, 2f, 2g and 2h.

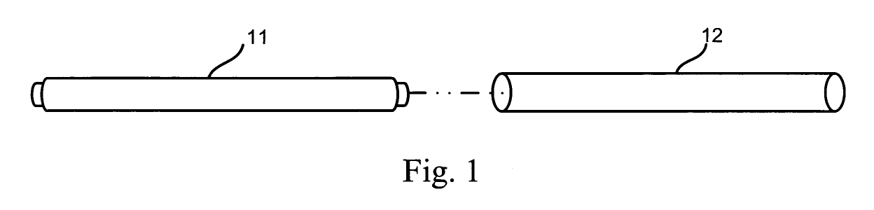

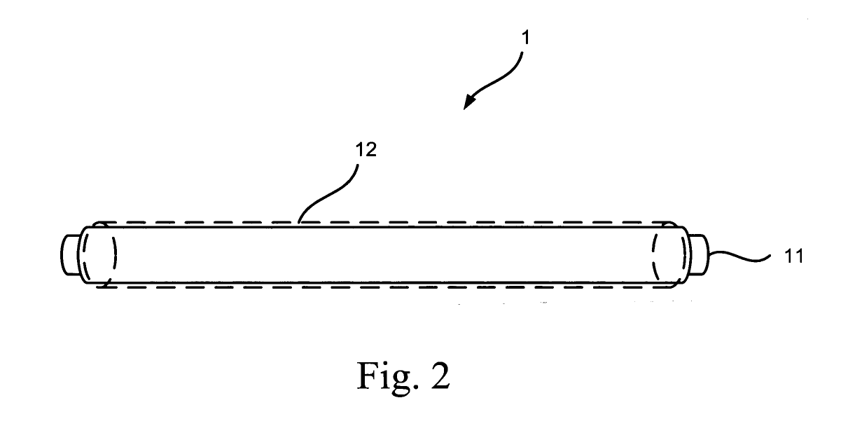

Referring to FIGS. 1 and 2, each of the wire units 1a, 1b, 1c, 1d, 1e, 1f, 1g and 1h includes a wire 11 and a sleeve 12 for protecting the wire 11 from hazardous substances of the environment according to the preferred embodiment of the present invention. The internal diameter of the sleeve 12 is marginally larger than the diameter of the wire 11. The sleeve 12 is made of a refractory material that can survive 150 degrees Celsius, acid, alkali and erosion. The sleeve 12 protects the wire 11 from light spots cast from the lens 3a, 3b, 3c, 3d, 3e, 3f, 3g and 3h.

In operation, the light spots are supposed to fall on the solar cells 2a, 2b, 2c, 2d, 2e, 2f, 2g and 2h. Should the light spots fall on the wire units 1a, 1b, 1c, 1d, 1e, 1f, 1g and 1h, the sleeves 12 would protect the wires 11 from the light spots. The temperature of the wires 11 will not be raised considerably. The properties of the wires 11 will not be changed considerably so that the performance of the concentration solar cell module will not be changed considerably. The wires 11 will not be damaged so that the service life of the concentration solar cell module will not be reduced. Moreover, the provision of the sleeves on the wires 11 is easy and inexpensive.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A solar cell module comprising:
a plurality of solar cells;
a plurality of wire units each comprising a wire for interconnecting two adjacent ones of the solar cells and a sleeve for receiving and protecting the wire from heat; and
a plurality of lenses over the solar cells for focusing light into light spots on the solar cells.

2. The solar cell module according to claim 1, wherein the internal diameter of the sleeve is marginally larger than the diameter of the wire.

3. The solar cell module according to claim 1, wherein the sleeve is made of a refractory material that survives 150 degrees Celsius.

4. The solar cell module according to claim 1, wherein the sleeve survives acid, alkali and erosion.
